(19) United States
(12) Patent Application Publication
(10) Pub. No.: US 2015/0311072 A1
(43) Pub. Date: Oct. 29, 2015

(54) METHOD OF PREPARING A SUBSTRATE FOR NANOWIRE GROWTH, AND A METHOD OF FABRICATING AN ARRAY OF SEMICONDUCTOR NANOSTRUCTURES

(71) Applicants: Gasp Solar ApS, Hedehusene (DK); UCL Business PLC, London (GB)

(72) Inventors: Martin Aagesen, Hedehusene (DK); Yunyan Zhang, London (GB); Jiang Wu, Milton Keynes (GB); Huiyun Liu, Milton Keynes (GB)

(73) Assignees: UCL Business PLC, London (GB); Gasp Solar ApS, Hedehusene (DK)

(21) Appl. No.: 14/692,231

(22) Filed: Apr. 21, 2015

(30) Foreign Application Priority Data
Apr. 25, 2014 (GB) 1407297.9

(51) Int. Cl. H01L 21/02; H01L 29/06; H01L 21/306; H01L 29/20

(52) U.S. Cl. CPC H01L 21/02603; H01L 29/20; H01L 29/0676; H01L 21/02538; H01L 21/02694; H01L 21/02636; H01L 21/30604

(57) ABSTRACT

The present invention provides a reproducible preliminary in-situ oxide removal step for patterned self-assisted III-V semiconductor nanowire growth. Here “in-situ” means located within the same treatment environment or apparatus as the nanowire growth process, e.g. with a molecular beam epitaxy (MBE) apparatus or the like. Providing an in-situ process may prevent the formation of a thin oxide layer during transfer of the substrate into the nanowire growth apparatus.

### FIELD OF THE INVENTION

The invention relates to the growth of semiconductor nanostructures, and in particular to the fabrication of an array of one-dimensional semiconductor nanostructures, e.g. nanowires or the like, by epitaxial growth on a substrate.

### BACKGROUND TO THE INVENTION

Epitaxial growth of Group III-V semiconductor nanowires, such as GaAs, GaAsP, InAs, InP, GaAsSb, InSb or InAsSb nanowires, is important in areas like sensors, LEDs and photovoltaics. Much research in this field focusses on optimizing the growth parameters used to produce the nanowire structures.

One known optimization is to avoid the use of a catalyst such as gold during growth in order to avoid contamination of the resulting nanowire crystal lattice or substrate. The optimization may be achieved by using a growth method known as “self-assisted growth”, or “self-catalysed growth”, in which for instance a gallium droplet is used to grow a Ga-based nanostructure, e.g. a GaAsP nanowire or an indium droplet is used to grow an InSb nanowire.

As the knowledge about self-catalysed growth of nanowires has been increased, it has been possible to grow one-dimensional semiconducting nanowires with unique properties. In order to utilize these properties it is desirable to be able to determine accurately the position of growth on the substrate surface, i.e. to fabricate a regular array of nanowires on a substrate. By accurately positioning nanowires with unique properties it is possible to fabricate better, or cheaper, electronic or optoelectronic devices. Research in this field focusses both on the substrate preparation prior to nanowire growth and on the growth parameters used for initiating the nanowire growth.

When growing non-positioned nanowires, such as Ga-assisted GaAs nanowires, a silicon substrate with a thin top layer of native oxide is often used as growth substrate. This growth method has been thoroughly described in the literature [1]. It is especially desirable to be able to grow positioned nanowires made from III-V materials on a silicon substrate since this will combine the highly desirable optoelectronic properties of the III-V material system with that of the low-cost, and well understood, silicon technology.

Typically, a fabrication method of self-assisted growth of an array of positioned III-V nanowires on a silicon substrate comprises the following steps:

(i) Prepare a silicon (111) substrate ready for epitaxial growth;

(ii) Deposit a thin layer of a material which prevents epitaxial growth from taking place on the silicon substrate. Typically SiO₂ is used for this with the SiO₂ having a thickness in the 10-60 nm range.

(iii) Etch holes through the deposited layer such that the clean silicon (111) crystal surface is exposed at the bottom of the holes. Typically the hole sizes are in the range of 30-150 nm in diameter. After this step the patterned substrates are ready to be loaded into the nanowire growth system but typically this is not done just after the SiO₂ etch, instead the substrates are stored until they are needed

(iv) Remove any oxide that regrows in the patterned holes on the substrate after step (iii), e.g. by dipping into an oxide removal etch material (e.g. hydrofluoric acid) just before loading into the nanowire growth system.

(v) Perform self-assisted growth inside the nanowire growth system using growth parameters that have been optimized for positioned growth. A typical growth temperature for Ga-assisted GaAs(P) nanowire growth is in the range of 600-640° C.

Step (iv) is performed because a thin oxide layer, e.g. having a thickness of 0.5-5 nm, may re-grow on the silicon surface at the bottom of the pattered holes because of their exposure to the ambient environment during the time from substrate patterning/hole-etching until loading into the nanowire growth system.

When performed positioned growth of an array of nanowires, it is desirable for the nanowires to exhibit the same direction of growth, e.g. perpendicular to the substrate surface to yield so-called vertical nanowires.

It is known that failure to remove all native oxide at the bottom of the etched holes before growing Ga-assisted GaAs nanowires can have an adverse effect on the nanowire growth [2]. It is thought necessary to have a short final etch in 1% HF just before loading the substrate into the nanowire growth system to be certain to remove any remaining oxide in the bottom of the holes. It is also suggested that in addition to the final external etch, it may be desirable to have an in-situ native oxide removal process since re-growth of native oxide layers occurs very quickly.

It has also been suggested that a 5 minute annealing step at 690° C. inside the nanowire growth system may contribute to a scheme for reproducibly growing positioned Ga-assisted GaAs nanowires on patterned silicon [7]. It is speculated that the annealing step may act to remove a thin regrown oxide that forms in the patterned holes during the substrate transfer and loading process and/or to clean the substrate by desorbing existing contaminants in the patterned holes.

It has also be suggested to perform a preliminary heating step at 770° C. for 30 minutes inside the nanowire growth system in order to remove any possible contaminants before growing positioned Ga-assisted GaAs nanowires on patterned silicon [8]. An increase in the yield of vertical nanowires was observed in this process.

### SUMMARY OF THE INVENTION

The inventors have realised that the known techniques for patterned self-assisted growth of III-V semiconductor nanowires discussed in the literature do not consistently or reproducibly result in a clean exposed silicon (111) surface ready for epitaxial overgrowth at the base of all etched holes.

One aspect of this realisation arises from the observation that it is possible to visually distinguish between a self-catalysed nanowire grown in a hole with a native oxide base and a nanowire grown in a hole without a native oxide base. If a native oxide layer is present, the nanowire growth preferentially occurs only at the specific location in the hole where growth initiates and does not “spread out” to cover all of the etched hole. This means that the sides of the hole remain visible even when the nanowire is fully grown (e.g. has a height of 1 μm or more, even 5 μm or more). The growth mechanism here is thus the same as in traditional non-positioned growth. In contrast, in the absence of a native oxide layer a thin layer of growth material used (e.g. GaAs) is deposited on the exposed substrate during the nanowire growth. The self-assisted nanowire growth is still located mainly around the specific spot in the hole where the growth initiated but while the nanowire grows a thin film of the growth material used for the nanowire growth is also deposited on the exposed silicon surface around the nanowire base at the bottom of the hole. This means that the hole can be completely filled by semiconductor material, whereby the edge of the hole ceases to be visible. This is true positioned growth.

Another aspect of this realisation is that the parameters for non-positioned growth can be optimised to increase the yield of vertical nanowires. This means that the adverse effects caused by the presence of the native oxide layer can be masked or compensated. For example, a technique of patterned Ga-assisted GaAs nanowire growth with up to 95% yield of vertical nanowires has been reported [6]. However, the etched holes are visible around the grown nanowires in the results of this technique, which indicates that the process was actually non-positioned growth. Moreover, the results of this technique are not easily reproducible.

At its most general, the present invention provides a reproducible preliminary in-situ oxide removal step for patterned self-assisted III-V semiconductor nanowire growth. Here “in-situ” means located within the same treatment environment or apparatus as the nanowire growth process, e.g. with a molecular beam epitaxy (MBE) apparatus or the like. Providing an in-situ process may prevent the formation of a thin oxide layer during transfer of the substrate into the nanowire growth apparatus.

The oxide removal step occurs before the start of the self-assisted nanowire growth process. Self-assisted growth typically begins with the deposition of the self-catalyst, e.g. Ga or In. The oxide removal step preferably occurs immediately before the deposition of the self-catalyst.

According to the invention, there is provided a method of preparing a substrate to support self-catalysed nanostructure growth, the method comprising: forming an array of holes in a treatment surface of a substrate; transferring the substrate into a nanostructure growth apparatus; and before beginning self-catalysed nanostructure growth, heating the substrate to selectively remove native oxide from the base of each hole in the array of holes. The method thus ensure that the substrate material is exposed at the bottom of the holes so that true positioned growth can occur.

The nanostructures are preferably one-dimensional nanostructures, such as nanowires. Herein “self-catalysed” means that the nanostructures are grown without using an separate catalyst particle (e.g. gold or the like). Self-catalysed nanostructures may contain fewer impurities for this reason.

Herein native oxide may mean an oxide layer formed naturally on the surface of the substrate through exposure to the ambient environment, e.g. air. For example, if the substrate is silicon, the native oxide may include one or more oxides of silicon. However, the native oxide may also include oxide material that has been purposefully deposited. For example, the array of holes may be formed within an oxide layer on the substrate. During formation of the holes, this oxide layer may not be fully penetrated to the substrate. Thus, a remnant of the oxide layer may exist at the base of each hole. This remnant may also be the “native oxide” that is removed by the selective de-oxidation step of the invention.

Herein, “selective” de-oxidation may mean that the parameters of the de-oxidation step are chosen so that the native oxide at the base of the holes may be removed (e.g. desorbed or evaporated) while the material defining the holes in the treatment surface (which may itself be a native oxide) is substantially unaffected. The relevant parameters for the de-oxidation step may include temperature and duration.

For example, the de-oxidation step may include or consist of heating the substrate to between 800° C. and 900° C. for 60 minutes or less, e.g. between 5 and 60 minutes, preferably between 10 and 30 minutes. The heating step may include a plurality of stages having different temperatures, or it may be a single heating step at a set temperature. Preferably, the de-oxidation step comprises or consists of heating the substrate to between 830° C. and 880° C. for between 10 and 20 minutes.

The de-oxidation step may be performed with or without a conventional oxide etch, e.g. a dip in HF acid. It may be desirable for no oxide etch process to be performed between forming the array of hole and transferring the substrate into the nanostructure growth apparatus. If an oxide etch is performed, it may be desirable to ensure that there are no air bubbles trapped in the holes. The method may therefore include, before dipping the substrate in the etching liquid, immersing the substrate in a deaeration liquid, e.g. deionised water or the like, in order to remove air bubbles from the plurality of holes. Alternatively, the oxide etch material may be mixed with a liquid that facilitates bubble removal, e.g. the HF product Sioetch MT 06/01 VLSI Selectipur from BASF.

The nanostructure growth apparatus may comprise a molecular beam epitaxy (MBE) system. The de-oxidation step may include subjecting the system to a flux of material (e.g. Ga atoms) during the step of heating the substrate to selectively remove native oxide. This may enable a lower temperature (e.g. 800° C.) to be used for the heating

The method may include fabricating the nanostructures after the native oxide has been selectively removed. Fabricating the nanostructure may comprise performing self-catalysed growth of III-V semiconductor nanowires, wherein each hole in the array of holes is arranged to support the growth of a single III-V semiconductor nanowire. The III-V semiconductor nanowires may be made from any combination of the group III materials Al, In, Ga and the group V materials As, P, Sb, e.g. any one of GaAs, GaAsP, InAs, InP, GaAsSb, InSb, InAsSb, InGaAs, InGaAsP, InGaP, AlAS, AlP, AlGaAs, AlGaP, etc. The III-V semiconductor nanowires may grow substantially perpendicular to the substrate surface. The yield of perpendicular III-V semiconductor nanowires may be 90% or more, preferably 95% or more.

The de-oxidation step is to ensure that the nanostructure growth takes place on the exposed substrate. If this happens, the hole will be filled by the nanostructure growth material once it grows beyond a certain height. Thus, the method may include continuing the nanowire growth until the height of each III-V semiconductor nanowire is more than five times (e.g. between 5 and 10 times) the diameter of its respective hole, whereby the hole is completely filled by its III-V semiconductor nanowire. It may be highly desirable to completely fill all of the etched hole around a grown nanowire with a layer of growth material. Even a nanometer-thin layer of oxide present at the bottom of the etched hole around the grown nanowire may have a significant effect on the final properties of the device. For example, if nanowires are grown without filling the holes and then have a semiconducting shell grown around them, e.g. for the purpose of surface passivation, then during growth of the shell a reaction can occur between the native oxide that is exposed in the unfilled hole and the shell growth material. This reaction may form an unwanted conductive path between the shell and the growth substrate. For example, if the nanowires are axial p-n structures, i.e. the lower half of the nanowire is doped p-type and the upper half is doped n-type, a conductive path (i.e. a short circuit) between an n-type passivation shell around the nanowire and the substrate, which is only meant to conductively contact the p-type part of the nanowire, will be detrimental to the desired device.

The present invention may also provide a semiconductor device that is produced from the method outlined above. The semiconductor device comprising: a substrate; a masking layer on a top surface of the substrate; and a plurality of self-catalysed III-V semiconductor nanowires projecting from the masking layer, wherein each self-catalysed III-V semiconductor nanowire: extends through a respective hole formed in the masking layer, has a base in contact with the substrate, and has a height that is at least five times greater than the diameter of its respective hole, and wherein each self-catalysed III-V semiconductor nanowire completely fills its respective hole. The self-catalysed III-V semiconductor nanowire may have a layered structure, e.g. in which different types of nanowire growth material are deposited in sequence. The hole may be thus filled by the self-catalysed III-V semiconductor nanowire and the nanowire growth material formed thereon. There may be a plurality of holes in the masking layer, e.g. arrange in a regular array, wherein more than 90% (preferably more than 95%) of the plurality of holes are filled with a respective self-catalysed III-V semiconductor nanowire.

The substrate may be made from silicon, and the masking layer may be silicon dioxide. Each III-V semiconductor nanowire may be made any combination of the group III materials Al, In, Ga and the group V materials As, P, Sb, e.g. from any one of GaAs, GaAsP, InAs, InP, GaAsSb, InSb and InAsSb.

### BRIEF DESCRIPTION OF THE DRAWINGS

Embodiments of the invention are discussed below with reference to the accompanying drawings, in which:

FIG. 1 is a plan view of a quadrant of a semiconductor wafer showing nanowire growth areas for a comparative example;

FIG. 2 is a scanning electron microscopy (SEM) image of nanowire growth at a first region in the comparative example;

FIG. 3 is a SEM image of nanowire growth at a second region in the comparative example;

FIG. 4 is a SEM image of nanowire growth at a third region in the comparative example;

FIG. 5 is a plan view of a quadrant of a semiconductor wafer showing nanowire growth areas for a first example of the invention;

FIG. 6 is a scanning electron microscopy (SEM) image of nanowire growth at a first region in the first example;

FIG. 7 is a SEM image of nanowire growth at a second region in the first example;

FIG. 8 is a SEM image of nanowire growth at a third region in the first example;

FIG. 9 is a SEM image of nanowire growth at a region in a second example;

FIG. 10 is a SEM image of nanowire growth at a region in a third example; and

FIG. 11 is a graphical flow diagram showing a patterning that can be used with the invention.

### DETAILED DESCRIPTION; FURTHER OPTIONS AND PREFERENCES

Research undertaken by the present inventors into the growth of positioned Ga-assisted GaAsP nanowires on a silicon substrate has revealed that known techniques for the removal of regrown oxide at the bottom of etched holes are often unsuccessful, even when the techniques are thought to be very thorough.

For example, it is known to perform an oxide etch, typically using hydrofluoric acid (HF). The oxide etch step is designed to remove only a very thin layer of oxide during the etching time. This in order to ensure that the entire layer of patterned SiO₂ is not also removed. The inventors have discovered that this oxide etch step is not always effective. There may be two reasons for this:

(a) a thin layer of oxide may regrow at the bottom of the holes during the brief time where the substrate is transferred from the oxide etch and loaded into the nanowire growth system, and

(b) the etched holes may trap small bubbles of air within them that can prevent the etch material (HF) from reaching the bottom of the hole to remove the oxide.

Thus, the remaining oxide layer in the holes may be a thin layer, e.g. 0.5-1 nm, which has regrown after initial etching, or it may be a thicker oxide layer, perhaps 1-5 nm, which has regrown over a longer time period and which then has not been successfully removed during the etching.

The present invention proposes an preliminary in-situ de-oxidation step to remove the oxide at the bottom of the holes without adversely affecting the hole structure. The invention may thus be used to make certain that self-assisted growth occurs on the exposed silicon and not on the native oxide.

When self-assisted growth of nanowires is carried out on a patterned substrate, the nanowire growth that occurs in holes which still have a thin layer of native oxide mimics the growth behaviour observed for non-positioned growth on silicon substrates [2]. During non-positioned growth of nanowires, a vast majority, sometimes close to 100%, of the nanowires can still be observed to grow perpendicular to the substrate surface. Growing such a high percentage of vertical non-positioned nanowires is however very difficult to do reproducibly since it depends heavily on the thickness of the native oxide layer. Often a significant percentage of non-vertical nanowires is grown during non-positioned nanowire growth and also there are many completely failed nanowire growth attempts. Thus, in the case of a patterned substrate where the etched holes having a thin layer of native oxide at their bottom, the nanowire growth process is essentially non-positioned growth, but just limited to the area covered by the etched hole. This means that although it is still possible to obtain a high yield of positioned vertical nanowires, then it is very difficult to reproduce these growths. More often than not a significant amount of non-vertical nanowires are produced and growth of non-nanowire formed material in the etched holes also occurs.

The invention aims to ameliorate the above problems by ensuring that growth takes place in holes without a native oxide layer therein. In these circumstances, the first stage of nanowire growth also results in the formation of a thin layer of semiconductor growth material (e.g. GaAs) on the exposed silicon substrate around the self-catalysed nanowire growth location.

Three examples of nanowire growth in which a preliminary de-oxidation step is used are discussed below. Firstly, a comparative example without a preliminary thermal de-oxidation step is described.

### Comparative Example

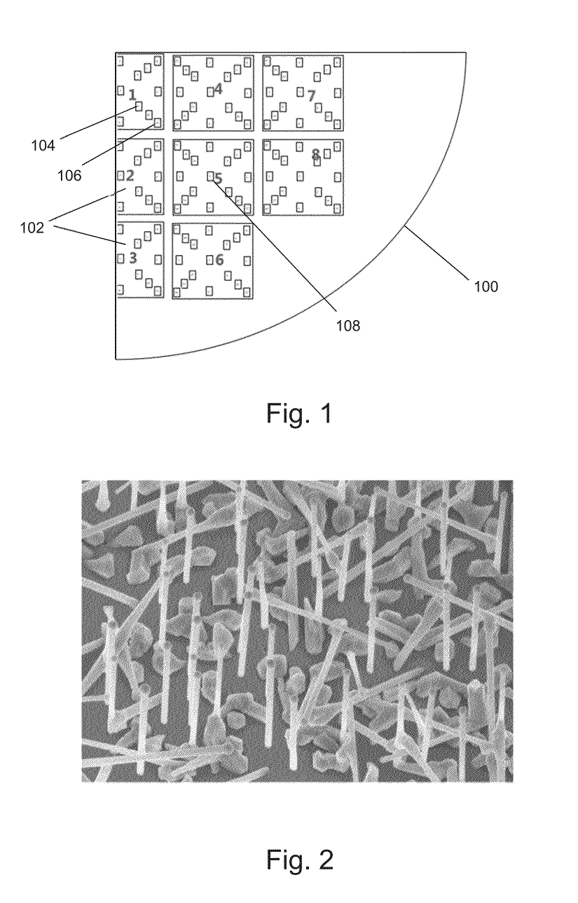

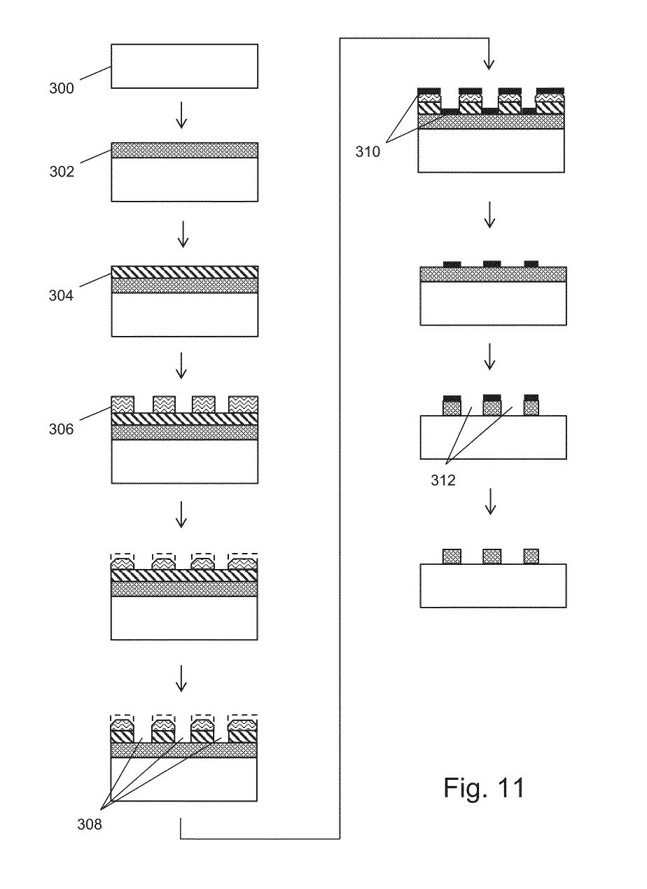

In the comparative example, growth of GaAsP nanowires on a patterned substrate was performed in an molecular beam epitaxy (MBE) apparatus in line with the stages set out in Table 1. The substrate was a quadrant of semiconductor wafer formed from p-type silicon. The treatment surface is a (111) surface on which a layer of silicon dioxide having a array of holes fabricated therein was formed using the method described below with reference to FIG. 11. FIG. 1 shows a plan view of the substrate 100. A number of different patterning regions 102 were formed on the surface.

TABLE 1
Growth parameters for comparative example

| | | | | | Time | T |
|---|---|---|---|---|---|---|
| | Ga Flux | V/III | As₂ Flux | P Flux | (mins) | (° C.) |
| Warm-up | — | — | 2.6 × 10⁻⁶ | 6.0 × 10⁻⁷ | 5 | |
| Growth | 1.6 × 10⁻⁷ | 20 | 2.6 × 10⁻⁶ | 6.0 × 10⁻⁷ | 40 | 638 |
| | 0.5 ml/s | | | | | |
| Stop/cool | 0 | — | 0 | ~0 | | 100 |

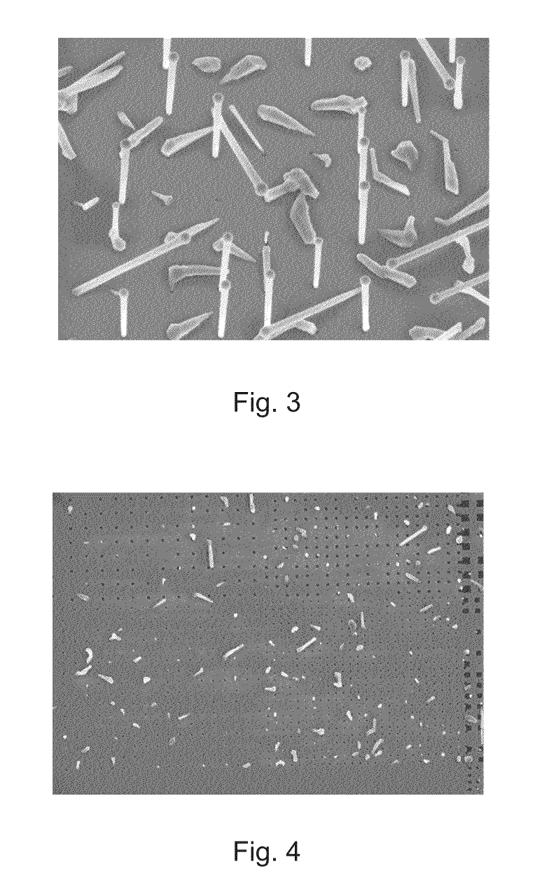

FIGS. 2, 3 and 4 are SEM images taken after the nanowire growth process at three respective sub-regions 104, 106, 108 on the substrate. FIGS. 2 and 3 depict sub-regions towards the edge of the substrate which have different areal density of patterned holes. It may be seen that the growth parameters are not fully optimised because growth has not occurred at all of the holes. However, the growth that has occurred does not display uniformity of growth direction.

FIG. 4 depicts a sub-region towards the centre of the substrate. Here there is little nanowire growth, because the growth parameters are not optimised and probably because the temperature at the centre of the substrate is too high.

### Example 1

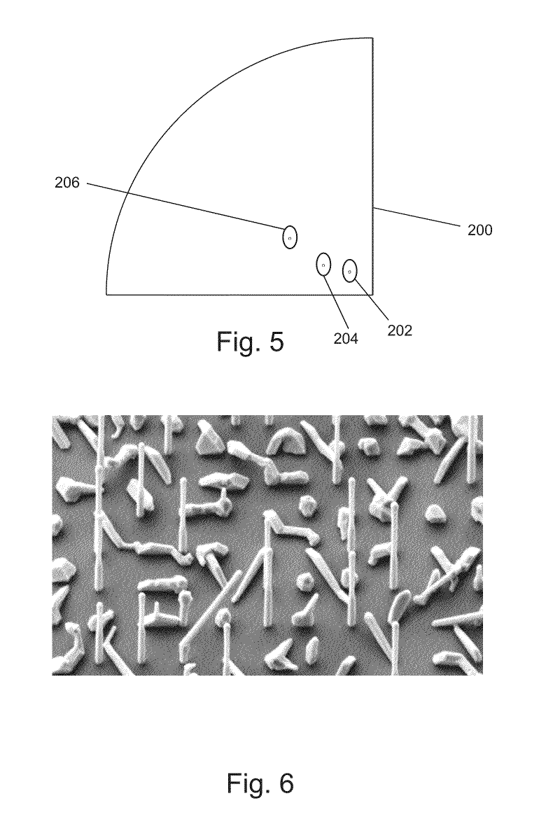

In example 1, growth of GaAsP nanowires on a patterned substrate was performed in an molecular beam epitaxy (MBE) apparatus in line with the stages set out in Table 2. Similarly to the comparative example above, the substrate was a quadrant of semiconductor wafer formed from p-type silicon., and the treatment surface was a (111) surface on which a layer of silicon dioxide having a array of holes fabricated therein was formed using the method described below with reference to FIG. 11. FIG. 5 shows a plan view of the substrate 200. FIGS. 6, 7 and 8 are SEM images taken at respective sub-regions 202, 204, 206 on the surface.

TABLE 2
Growth parameters for example 1

| | | | | | Time | T |
|---|---|---|---|---|---|---|
| | Ga Flux | V/III | As₂ Flux | P Flux | (mins) | (° C.) |
| De-ox 1 | — | — | — | — | 5 | 900 |
| De-ox 2 | — | — | — | — | 10 | 880 |
| Warm-up | — | — | 2.6 × 10⁻⁶ | 6.1 × 10⁻⁷ | 5 | |
| Growth | 1.6 × 10⁻⁷ | 20 | 2.6 × 10⁻⁶ | 6.1 × 10⁻⁷ | 40 | ~638 |
| | 0.5 ml/s | | | | | |
| Stop/cool | 0 | — | 0 | ~0 | | 100 |

Example 1 thus differs from the comparative example due to the presence of a preliminary de-oxidation step in which the substrate is heated in the MBE apparatus before the nanowire growth begins. In this example the preliminary de-oxidation step has two stages: a first stage at 900° C. followed by a second stage at 880° C. The aim of the de-oxidation step is to remove all native oxide from the bottom of the patterned holes before nanowire growth begins.

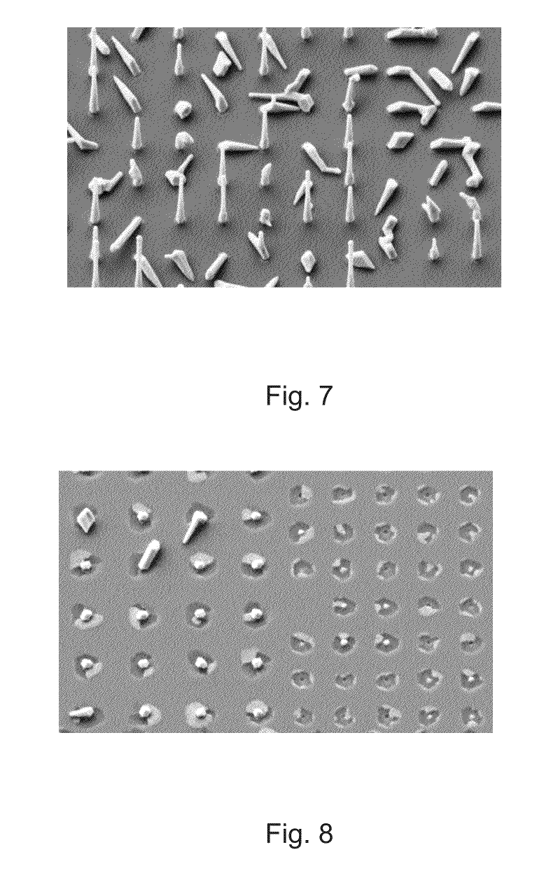

FIGS. 6 and 7 depict sub-regions towards the edge of the substrate. Although nanowire growth is still not fully optimised, it may be same that the growth direction is improved relative to the comparative example, and that where growth has occur the holes are completely filled, which indicates that growth has taken place from an exposed silicon surface.

FIG. 8 depicts a sub-region closer to the centre of the substrate. Here there is very little growth, and it can be seen that the silicon dioxide layer around the etched holes has started to desorb. This indicates that the temperature for the de-oxidation step must be controlled to provide a selective de-oxidation function in which the native oxide at the bottom of the holes is removed without adversely affecting the structure of the holes.

### Example 2

In example 2, growth of GaAsP core nanowires on a patterned substrate was performed in an molecular beam epitaxy (MBE) apparatus in line with the stages set out in Table 3. The process was set up in the same way as example 1.

TABLE 3
Growth parameters for example 2

| | | | | | Time | T |
|---|---|---|---|---|---|---|
| | Ga Flux | V/III | As₄ Flux | P Flux | (mins) | (° C.) |
| De-ox | — | — | — | — | 20 | 832 |
| Ga deposit | 1.6 × 10⁻⁷ | — | — | — | 1 | 600 |
| | 0.5 ml/s | | | | | |
| Growth 1 | 1.6 × 10⁻⁷ | 3 | 3.7 × 10⁻⁷ | 1.1 × 10⁻⁷ | 5 | 600 |
| | 0.5 ml/s | | | | | |
| Growth 2 | 1.6 × 10⁻⁷ | 6 | 8.5 × 10⁻⁷ | 1.1 × 10⁻⁷ | 10 | 600 |
| | 0.5 ml/s | | [in 30 s] | | | |
| Growth 3 | 1.6 × 10⁻⁷ | 10 | 1.40 × 10⁻⁶ | 2.0 × 10⁻⁷ | 10 | 600 |
| | 0.5 ml/s | | [in 30 s] | | | |
| Growth 4 | 1.6 × 10⁻⁷ | 15 | 2.11 × 10⁻⁶ | 2.9 × 10⁻⁷ | 5 | 600 |
| | 0.5 ml/s | | [in 30 s] | [in 30 s] | | |
| Growth 5 | 1.6 × 10⁻⁷ | 20 | 2.82 × 10⁻⁶ | 3.8 × 10⁻⁷ | 15 | 600 |
| | 0.5 ml/s | | [in 30 s] | [in 30 s] | | |
| Stop/cool | 0 | — | 8.5 × 10⁻⁷ | 1.1 × 10⁻⁷ | | 100 |
| | | | [in 0 s] | [in 0 s] | | |

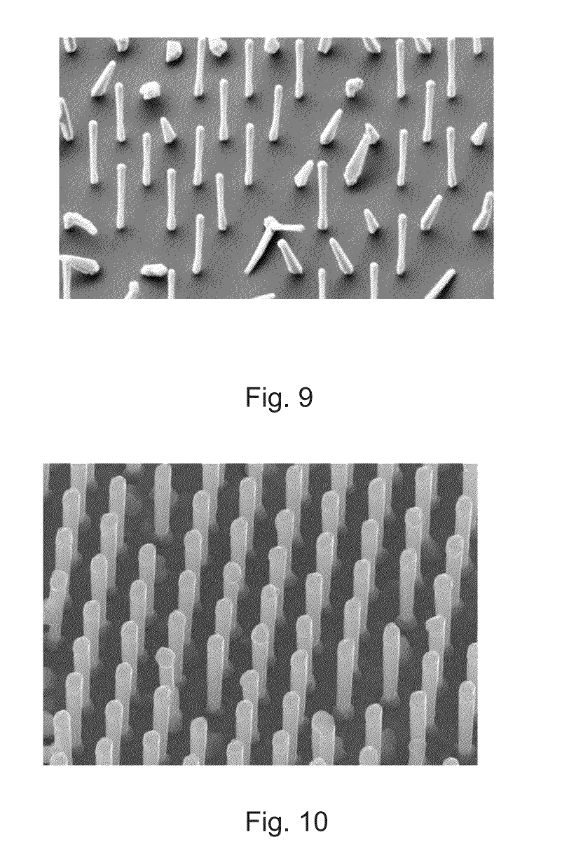

In this example, the preliminary de-oxidation process is a single stage, performed at a lower temperature but for a longer period than in example 1. FIG. 9 is an SEM image showing the results of this growth process. Again it may be seen that the nanowire growth completely fills the holes, which indicates that growth on an exposed silicon surface has occurred.

### Example 3

In example 3, growth of core-shell nanowires on a patterned solar cell substrate was performed in an molecular beam epitaxy (MBE) apparatus in line with the stages set out in Table 4. The process was set up in the same way as example 1.

TABLE 4
Growth parameters for example 3

| | | | | | | Time | T | |
|---|---|---|---|---|---|---|---|---|
| | Ga Flux | In Flux | V/III | As₄ Flux | P Flux | (mins) | (° C.) | Doping |
| De-ox | — | — | — | — | — | 20 | 832 | — |
| Ga deposit | 1.6 × 10⁻⁷ | — | — | — | — | 1 | 600 | — |
| | 0.5 ml/s | | | | | | | |
| Growth 1 | 1.6 × 10⁻⁷ | — | 3 | 3.7 × 10⁻⁷ | 1.1 × 10⁻⁷ | 5 | 600 | Be |
| | 0.5 ml/s | | | | | | | 1.5 × 10⁻¹⁷ |
| Growth 2 | 1.6 × 10⁻⁷ | — | 6 | 8.5 × 10⁻⁷ | 1.1 × 10⁻⁷ | 10 | 600 | Be |
| | 0.5 ml/s | | | [in 30 s] | | | | 1.5 × 10⁻¹⁷ |
| Growth 3 | 1.6 × 10⁻⁷ | — | 10 | 1.40 × 10⁻⁶ | 2.0 × 10⁻⁷ | 10 | 600 | Be |
| | 0.5 ml/s | | | [in 30 s] | | | | 1.5 × 10⁻¹⁷ |
| Growth 4 | 1.6 × 10⁻⁷ | — | 15 | 2.11 × 10⁻⁶ | 2.9 × 10⁻⁷ | 5 | 600 | Be |
| | 0.5 ml/s | | | [in 30 s] | [in 30 s] | | | 1.5 × 10⁻¹⁷ |
| Growth 5 | 1.6 × 10⁻⁷ | — | 20 | 2.82 × 10⁻⁶ | 3.8 × 10⁻⁷ | 15 | 600 | Be |
| | 0.5 ml/s | | | [in 30 s] | [in 30 s] | | | 1.5 × 10⁻¹⁷ |
| Pause 1 | 0 | — | — | 2.82 × 10⁻⁶ | 3.8 × 10⁻⁷ | 10 | 485 | — |
| Pause 2 | 0 | — | — | 6.7 × 10⁻⁶ | 2.9 × 10⁻⁶ | 10 | 485 | — |
| Shell-p | 1.6 × 10⁻⁷ | — | 60 | 6.7 × 10⁻⁶ | 2.9 × 10⁻⁶ | 6 | 485 | Be |
| | 0.5 ml/s | | | | | | | 5 × 10⁻¹⁶ |
| Shell-i | 1.6 × 10⁻⁷ | — | 60 | 6.7 × 10⁻⁶ | 2.9 × 10⁻⁶ | 20 | 485 | — |
| | 0.5 ml/s | | | | | | | |
| Shell-n | 1.6 × 10⁻⁷ | — | 60 | 6.7 × 10⁻⁶ | 2.9 × 10⁻⁶ | 40 | 485 | Si |
| | 0.5 ml/s | | | | | | | 1 × 10⁻¹⁸ |
| Surface | 1.6 × 10⁻⁷ | 9.2 × 10⁻⁸ | 30 | 0 | 7.56 × 10⁻⁶ | 10 | 485 | Si |
| passivation | 0.5 ml/s | | | | | | | 3 × 10⁻¹⁸ |
| | | | | | | | | [in 3 min] |
| Contact | 0 | 9.2 × 10⁻⁸ | 82 | 0 | 7.56 × 10⁻⁶ | 12 | 485 | Si |
| layer | | | | | | | | 3 × 10⁻¹⁸ |
| Stop/cool | 0 | — | — | 0 | 7.56 × 10⁻⁶ | | 100 | |

In this example, the de-oxidation step is the same as that used in example 2. FIG. 10 is a SEM image shows the result of this growth process. Again it can be seen that the nanowire growth completely fills the holes, which indicates that growth on an exposed silicon surface has occurred. This example also exhibits good uniformity of growth direction. In practice, both the temperature and duration of the de-oxidation step need to be set to ensure that all the native oxide within the holes is removed, but without adversely affecting the structure of the holes.

In the examples above, the native oxide layer in the holes is removed by means of a high temperature selective de-oxidation step. In other words, temperature alone is used as the controlling parameter. However, it is also possible to perform gallium-assisted de-oxidation by supplying a suitable Ga flux during the de-oxidation step [2].

To select the temperature for the de-oxidation step, it is known that a thin layer (e.g. having thickness of 0.6-1 nm) of native oxide at the bottom of the holes starts to desorb or evaporate at temperatures above 700° C. [3]. Thicker oxide layers, e.g. having a thickness of 2.5 nm or more, may require temperatures of 800° C. or more in order to evaporate [4].

However, the work of the inventors has shown that the thicker layer of thermally grown SiO₂ in which the pattern of holes is grown requires temperatures closer to 900° to desorb. Thus, there is a range of selective de-oxidation temperatures, e.g. of about 800° C. to 880° C. (preferably 830° C. to 880° C.) for silicon substrates, in which the native oxide on the bottom of the holes is removed without affecting the patterned layer. The duration of the de-oxidation step is also relevant. The rate at which the native oxide desorbs strongly depends on the temperature (probably exponentially). This means that in principle de-oxidation can occur at temperatures below 800° C., but the required duration is likely to be impractical. The inventors have found that for selective de-oxidation temperatures in the range 830° C. to 880° C. a duration of up to 30 minutes, e.g. between 10 and 20 minutes provides the necessary effect.

If the oxide is removed by means of a gallium-assisted de-oxidation method, a lower substrate temperature may be used, e.g. 800° C. [5].

In principle, it is possible for the selective de-oxidation step of the present invention to obviate the requirement for the HF oxide etch discussed above. Omitting the HF oxide etch may be desirable for two reasons. Firstly, the HF oxide etch acts to erode the patterned SiO₂ layer itself, which manifest itself as an increase in the diameter of the holes. Moreover, the HF oxide etch can contaminate the substrate surface, which can be detrimental to subsequent nanowire growth. Secondly, hydrofluoric acid is a dangerous substance, and thus must be handled with great precaution in a silicon-processing lab. If it were not needed, processing would be made much simpler and safer.

However, the present invention may be used in conjunction with a HF oxide etch. Indeed, the thermal de-oxidation step in the nanowire growth apparatus may also act to desorb or evaporate any contaminants that remain on the substrate surface after the HF oxide etch.

An exemplary HF oxide etch may comprise the following steps:
1) Mix 50 ml of 5% HF solution with 220 ml deionised (DI) water in a PTFE beaker. Ensure that the temperature of the mixed ˜0.9% solution is in the range of ˜21-24° C.
2) Fill another beaker with DI water.
3) Put the substrate into the DI water for 5 min (this is to ensure that no air bubbles are trapped in the etched holes during the actual HF etch).
4) Remove the substrate from the DI water and immediately dip it into the ˜0.9% HF mixture for 20 seconds while gently moving the substrate back and forth.
5) Remove substrate from HF mixture and flush thoroughly, preferably with isopropyl alcohol (although methanol or DI water can also be used).
6) Blow dry with nitrogen
7) Load substrate into the nanowire growth system as quickly as possible, preferably within 5 minutes.

The present invention may be applied to any type of patterned substrate suitable for nanowire growth. Etching techniques for forming an array of holes in a top layer of a semiconductor are well known. FIG. 11 illustrates an exemplary process that was used to prepare the substrates used the examples discussed above.

The process in FIG. 11 begins with a clear double-sided polished silicon wafer 300. A layer of silicon dioxide 302 is grown on the wafer 300 in a dry oxidation process, e.g. at 700° C. for 20 minutes. A global etch stage may follow this step in order to control the thickness of the SiO₂ layer 302. The layer may be controlled to have a thickness of 40 nm.

Next a planarization layer 304 is spin-coated onto the SiO2 layer 302. The planarization layer may be formed from a micro resist material having a thickness of 46 nm. The top of the planarization layer 304 is then printed with imprint material to form a residual layer 306, which defines an inverse image of the array of holes. The imprint material may be J-FIL, manufactured by Molecular Imprints, Inc.

Next the residual layer 306 is etched by a first reactive ion etch (RIE) process to ensure that no imprint material exists on the inverse image of the holes. The planarization layer 304 is then etched by a second RIE process. The residual layer protects the portions of the planarization layer that it covers, so the result of the second RIE process is holes 308 in the planarization layer 304 that match the holes in the residual layer.

Next a layer of aluminium 310 is deposited on the substrate, e.g. using an electron beam-induced deposition process. The aluminium layer covers the base of the holes as well as the top of the residual layer 306.

Next the remnants of the planarization layer 304 and the residual layer 306 are lifted off by dipping the substrate in a suitable remover material, e.g. Microposit 1165 Remover. This leaves the substrate 300 and SiO₂ layer 302 with a pattern of aluminium 308 thereon which defines the location of the holes.

Next the portions of the SiO₂ layer 302 that are not covered by aluminium are etched away using a third RIE process. It is common for the parameters of this step to be set such that a small thickness (e.g. 5 to 10 nm) of SiO₂ remains within the holes in order to prevent the silicon itself from being contaminated or otherwise damaged by the third RIE etch process. A result of this step is that a series of holes 312 are formed in the SiO₂ layer 302.

Next the aluminium layer 310 is removed from the SiO₂ layer 302 be dipping the substrate in a suitable remover, such as Microposit MF-322 Developer. The substrate is now patterned ready for use. The remaining SiO₂ material in the holes may be removed by an HF oxide etch step as discussed above or by the preliminary de-oxidation step in the nanowire growth apparatus.

One possible result of applying the present invention is to ensure that the nanowire growth truly occurs on the exposed silicon at the base of each hole. Another aspect of the invention is a means for inspecting an array of nanowires grown on a patterned substrate to ascertain whether or not the growth has occurred on the exposed silicon.

It is known that the bottom of a grown nanowire often becomes thicker as function of growth time. However, despite this fact, when nanowire growth occurs in holes with a native oxide layer, it is often still possible to see the etched hole around the nanowire even when the height of the nanowire is 5 μm.

The same effect is not observed when nanowire growth occurs in holes without a native oxide layer at the bottom. Of course, for very short nanowire growth times the epitaxial layer does not have sufficient time to form around the nanowire and fill the hole. However, the inventors have ascertained empirically that if an etched hole is free from oxide before nanowire growth then the nanowire growth material will completely fill the etched hole when the height of the nanowire is more than 5 to 10 times the diameter of the hole. This empirical test provides a simple means for determining whether or not an etched hole was free from oxide before nanowire growth.

The present invention may be used in the fabrication process for forming a well-defined array of positioned semiconductor nanostructures, e.g. one-dimensional nanowires, nanoflakes or the like. One advantage of forming a well-defined array is to ensure that all of the nanowires have uniform properties. If nanostructure are randomly spaced on a surface then some of the nanowires will shade unevenly for each other during their growth and this will affect their individual properties. Another advantage of forming a well-defined array is to ensure the substrate surface area on which the nanowires are grown is utilised in the most effective manner. For example, if there are missing nanowires then the efficiency of the macroscopic structure per unit area will decrease. For example, the light output from a light emitting diode or the conversion efficiency of a solar cell will both be lower if nanowires are missing. For electronic designs in which it is advantages to include a semiconductor nanowire it is desirable to know the exact position of the nanowire, e.g. to form contacts easily.

### REFERENCES

[1] P. Krogstrup, R. Popovitz-Biro, E. Johnson, M. H. Madsen, J. Nygaard, and H. Shtrikman, “Structural Phase Control in Self-Catalyzed Growth of GaAs Nanowires on Silicon (111),” Nano Lett., vol. 10, pp. 4475-4482, 2010.
[2] S. J. Gibson, J. P. Boulanger, and R. R. LaPierre, “Opportunities and pitfalls in patterned self-catalyzed GaAs nanowire growth on silicon,” Semicond. Sci. Technol., vol. 28, no. 10, p. 105025, October 2013.
[3] Y. Kobayashi and K. Sugii, “Thermal decomposition of very thin oxide layers on Si (111),” J. Vac. Sci. Technol. Vac. Surfaces Films, vol. 10, no. 4, pp. 2308-2313, 1992.
[4] D. C. Streit and F. G. Allen, “Thermal and Si-beam assisted desorption of SiO2 from silicon in ultrahigh vacuum,” J. Appl. Phys., vol. 61, no. 8, p. 2894, 1987.
[5] M. H. Madsen, M. Aagesen, P. Krogstrup, C. SU00F8rensen, and J. Nyg\aard, “Influence of the oxide layer for growth of self-assisted InAs nanowires on Si (111),” Nanoscale Res. Lett., vol. 6, no. 1, p. 516, 2011.
[6] S. Plissard, G. Larrieu, X. Wallart, and P. Caroff, “High yield of self-catalyzed GaAs nanowire arrays grown on silicon via gallium droplet positioning,” Nanotechnology, vol. 22, p. 275602, 2011.
[7] A. M. Munshi, D. L. Dheeraj, V. T. Fauske, D. C. Kim, J. Huh, J. F. Reinertsen, L. Ahtapodov, K. D. Lee, B. Heidari, A. T. J. van Helvoort, B. O. Fimland, and H. Weman, “Position-Controlled Uniform GaAs Nanowires on Silicon using Nanoimprint Lithography,” Nano Lett., p. 140129125009004, January 2014.
[8] M. Heiss, E. Russo-Averchi, A. Dalmau-Mallorquí, G. Tütüncü\check{g}lu, F. Matteini, D. Rüffer, S. Conesa-Boj, O. Demichel, E. Alarcon-Lladó, and A. Fontcuberta i Morral, “III-V nanowire arrays: growth and light interaction,” Nanotechnology, vol. 25, no. 1, p. 014015, January 2014.

1. A method of preparing a substrate to support self-catalysed nanostructure growth, the method comprising:
forming an array of holes in a treatment surface of a substrate;
transferring the substrate into a nanostructure growth apparatus; and
before beginning self-catalysed nanostructure growth, heating the substrate to selectively remove native oxide from the base of each hole in the array of holes.

2. A method according to claim 1, wherein heating the substrate to selectively remove native oxide includes heating the substrate to between 800° C. and 900° C. for 60 minutes or less.

3. A method according to claim 1, wherein heating the substrate to selectively remove native oxide includes heating the substrate to between 830° C. and 880° C. for 30 minutes or less.

4. A method according to claim 1, wherein heating the substrate to selectively remove native oxide includes heating the substrate to between 830° C. and 880° C. for between 10 and 20 minutes.

5. A method according to claim 1, further comprising, before transferring the substrate into the nanostructure growth apparatus, performing a oxide etch to remove native oxide from the substrate.

6. A method according to claim 5, wherein performing the oxide etch includes dipping the substrate in an etching liquid.

7. A method according to claim 6, wherein the etching liquid is hydrofluoric acid.

8. A method according to claim 1, further comprising, before dipping the substrate in the etching liquid, immersing the substrate in a deaeration liquid in order to remove air bubbles from the plurality of holes.

9. A method according to claim 1, wherein the etching liquid includes a deaeration liquid in order to remove air bubbles from the plurality of holes.

10. A method according to claim 1, wherein no oxide etch process is performed between forming the array of holes and transferring the substrate into the nanostructure growth apparatus.

11. A method according to claim 1, wherein the substrate is made from silicon, and the native oxide comprises one or more oxides of silicon.

12. A method according to claim 1, wherein the nanostructure growth apparatus is a molecular beam epitaxy (MBE) system.

13. A method according to claim 12, wherein the substrate is subjected to a flux of Ga atoms during the step of heating the substrate to selectively remove native oxide.

14. A method according to claim 1, further comprising, after heating the substrate to selectively remove native oxide from the base of each hole in the array of holes, performing self-catalysed growth of III-V semiconductor nanowires, wherein each hole in the array of holes is arranged to support the growth of a single III-V semiconductor nanowire.

15. A method according to claim 14, wherein the III-V semiconductor nanowires are made from any combination of the group III materials Al, In, Ga and the group V materials As, P, Sb.

16. A method according to claim 15, wherein the III-V semiconductor nanowires are made from any one of GaAs, GaAsP, InAs, InP, GaAsSb, InSb and InAsSb.

17. A method according to claim 14, wherein when the height of each III-V semiconductor nanowire is more than five times the diameter of its respective hole, the hole is completely filled by the III-V semiconductor materials used to grow the nanowire.

18. A semiconductor device comprising:
a substrate;
a masking layer on a top surface of the substrate; and
a plurality of self-catalysed III-V semiconductor nanowires projecting from the masking layer,
wherein each self-catalysed III-V semiconductor nanowire:
extends through a respective hole formed in the masking layer,
has a base in contact with the substrate, and
has a height that is at least five times greater than the diameter of its respective hole, and
wherein each hole is completely filled by its respective self-catalysed III-V semiconductor nanowire.

19. A semiconductor device according to claim 18 having a plurality of holes in the masking layer, wherein more than 90% of the plurality of holes are filled with a respective self-catalysed III-V semiconductor nanowire.

20. A semiconductor device according to claim 18, wherein the substrate is made from silicon, and the masking layer is silicon dioxide.

21. A method according to claim 18, wherein the III-V semiconductor nanowires are made from any combination of the group III materials Al, In, Ga and the group V materials As, P, Sb.
